(19) United States
(12) Patent Application Publication
(10) Pub. No.: US 2005/0278596 A1
(43) Pub. Date: Dec. 15, 2005

(54) Semiconductor integrated circuit device

(75) Inventors: Kentaro Miyajima, Akishima (JP); Atsushi Okumura, Hamura (JP); Masaki Kohno, Ome (JP)

Correspondence Address: MILES & STOCKBRIDGE PC, 1751 PINNACLE DRIVE, SUITE 500, MCLEAN, VA, 22102-3833, US

(73) Assignee: Hitachi, Ltd.

(21) Appl. No.: 11/136,454

(22) Filed: May 25, 2005

(30) Foreign Application Priority Data
May 27, 2004 (JP) 2004-157195

(51) Int. Cl. G01R 31/28; G06F 11/00

(52) U.S. Cl. 714/736

(57) ABSTRACT

Components are provided including: an expected-value generating circuit that generates, upon reception of an output signal directed from the interface unit to the internal processing circuit; an expected-value signal for detecting an error in the output signal, a comparing and determining circuit that compares the output signal and the expected-value signal to determine whether these signals match with each other; and an output processing circuit that retains the determination result of the comparing and determining circuit and performs a process for externally outputting the determination result. In the case where a test pattern, which is an M-series pseudo-random-number signal, is input from a pulse generator or the like to the I/F unit for testing, a circuit based on a logic of generation of such an M-series pseudo-random-number signal is provided in the expected-value generating circuit.

### CROSS-REFERENCE TO RELATED APPLICATION

The present application claims priority from Japanese Patent Application No. JP 2004-157195 filed on May 27, 2004, the content of which is hereby incorporated by reference into this application.

### TECHNICAL FIELD OF THE INVENTION

The present invention relates to semiconductor integrated circuit devices and, particularly, to a technology effective for a semiconductor integrated circuit device that tests an interface unit of a memory Large Scale Integration circuit (LSI) comprising a high-speed interface.

### BACKGROUND OF THE INVENTION

For example, for the purpose of testing a memory portion of a memory LSI or memory-combined LSI, a memory tester is used. The memory tester is highly functional and capable so as to exhaustively test the memory LSI, but at the same time, is extremely expensive. In recent years, with the enhanced speed of the memory LSI, a memory tester with a speed performance of 1 Gbps/pin has emerged.

Also, testing schemes independent from a memory tester includes a scheme of testing a memory LSI as being mounted on a system to be actually used (such a system is hereinafter abbreviated as an actual device) and a scheme of testing a memory LSI with a Built In Self Test (BIST) circuit being mounted thereon. Such a BIST circuit for memory LSI performs, for example, a writing test and a reading test on a memory array portion. In this case, the BIST circuit includes a function of generating an address and write data for the memory array portion and a function of generating an expected value to evaluate read data from the memory array portion.

### SUMMARY OF THE INVENTION

As a result of studies conducted by the inventors regarding technology of testing such memory LSI described above, the following has become apparent.

For example, in recent years, with the acceleration of speed enhancement of a memory LSI for cache memory, there is concern that the speed performance of the memory tester may not catch up with that of the memory LSI particularly at a product development stage. Moreover, with the advance of speed enhancement, it is predicted that, prior to the previously common malfunctions of the memory array portion, malfunctions caused by an interface unit (which may hereinafter be abbreviated as an I/F unit) in charge of signal inputs from and outputs to the outside will increase.

When a malfunction occurs in the interface unit, it is likely difficult for the memory tester to locate or analyze the malfunction even if the memory tester has a satisfactory speed performance. Furthermore, such a BIST circuit as described above are mainly aimed at testing the memory array portion, and therefore a test pattern may be supplied not via the I/F unit, in some cases. Therefore, it may be impossible to detect a malfunction in the I/F unit. Still further, in a test with the use of the actual device, in addition to the difficulty in locating a malfunction, there are concerns that a malfunction cannot possibly be detected depending on test conditions of the actual device and the like, and also concerns about the length of the test.

An object of the present invention is to provide a semiconductor integrated circuit device capable of testing a memory LSI, particularly, its interface unit.

The above and other objects and new features of the present invention will become apparent from the description of the specification and the attached drawings.

A summary of typical aspects of the present invention disclosed herein is described as follows.

A semiconductor integrated circuit device according to the present invention includes: an interface circuit that takes in an externally input signal and outputs the taken-in input signal to an internal processing circuit; a circuit that generates, upon receiving the output signal from the interface circuit, an expected-value signal for detecting an error in signal transmission in the interface circuit; a comparing and determining circuit that compares the output signal from the interface circuit and the expected-value signal to determine whether the output signal and the expected-value signal match with each other; and an output processing circuit that retains the determination result of the comparing and determining circuit and performs a process for externally outputting the determination result upon external request.

With this structure, without using an expensive memory tester or the like, an input signal is supplied by using, for example, an inexpensive pulse generator capable of a high-speed operation, thereby making it possible to test the interface unit. Also, the interface unit can be tested on a standalone basis. Therefore, malfunctions in the interface unit and those in a transmission route from the outside to the interface unit, tracking down of which has been difficult in conventional technology, can be found early and track down.

Here, for example, when the externally input signal is a pseudo-random-number signal generated by a first shift register having a specific number of stages and an input logic of a first EXOR circuit to the shift register, the circuit that generates the expected-value signal can be constructed by, for example, a second shift register having a number of stages equal to the specific number of stages of the first shift register and a second EXOR circuit having an input logic identical to the input logic of the first EXOR circuit.

With this, the circuit that generates the expected-value signal can be easily achieved. Also, since a pseudo-random-number signal can be used, it is possible to perform a test with a high test coverage along the line of an actual operation.

Also, a semiconductor integrated circuit device according to the present invention includes: an interface circuit that takes in a preset input test pattern in synchronization with a clock signal and outputs the preset input test pattern to an internal processing circuit; a circuit that predicts, based on the preset input test pattern, an output pattern directed from the interface circuit to the internal processing circuit and generates an expected value pattern for detecting whether an error is present in the output pattern; and a comparing and determining circuit that compares, for each cycle of the clock signal, the output pattern and the expected value pattern and generates either one of a matching signal and a non-matching signal.

Furthermore, a semiconductor integrated circuit device according to the present invention includes: a first interface circuit that receives an input of an address test pattern, takes in the input address test pattern in synchronization with a clock signal, and outputs a first output pattern to an internal memory circuit; a second interface circuit that receives an input of a data test pattern, takes in the input data test pattern in synchronization with the clock signal, and outputs a second output pattern to an internal memory circuit; a first expected-value generating circuit that generates a first expected-value pattern upon reception of the first output pattern; a second expected-value generating circuit that generates a second expected-value pattern upon reception of the second output pattern; a first comparing and determining circuit that compares the first output pattern and the first expected-value pattern and determines whether or not the first output pattern and the first expected-value pattern match with each other; a second comparing and determining circuit that compares the second output pattern and the second expected-value pattern and determines whether or not the second output pattern and the second expected-value pattern match with each other; and an output processing circuit that retains the determination result of the first comparing and determining circuit and the determination result of the second comparing and determining circuit respectively, and performs a process for externally outputting the decision result upon external request.

The address test pattern and the data test pattern are each generated by a first shift register having a specific number of stages and an input logic of a first EXOR circuit to the shift register. The first expected-value generating circuit includes a second shift register having a number of stages equal to the number of stages of the first shift register that generates the address test pattern and includes a second EXOR circuit having an input logic identical to the input logic of the first EXOR circuit. The second expected-value generating circuit includes a third shift register having a number of stages equal to the number of stages of the first register that generates the data test pattern and includes a third EXOR circuit having an input logic identical to the input logic of the first EXOR circuit.

As such, an expected-value generating circuit and a comparing and determining circuit are provided for each signal of the same system, such as address or data, thereby allowing simultaneous tests to be performed under appropriate conditions for each signal system. Furthermore, when a malfunction occurs, the malfunction can be easily located.

Here, either one of the first interface circuit and the second interface circuit may be provided with a plurality of either of the first expected-value generating circuits and the second expected-value generating circuits having different structures and a plurality of either of the first comparing and determining circuits and the second comparing and determining circuits having different structures. With this, a test can be performed with a plurality of test patterns, thereby further increasing the test coverage.

Furthermore, when a plurality of the first interface circuits and a plurality of the second interface circuits are present, it is preferable that the semiconductor integrated circuit device further includes: a first selector circuit that receives inputs from the plurality of first interface circuits for output to one of the first comparing and determining circuits; and a second selector circuit that receives inputs from the plurality of second interface circuits for output to one of the second comparing and determining circuits. With this, the circuit size can be reduced, for example.

### BRIEF DESCRIPTIONS OF THE DRAWINGS

FIG. 1 is a block diagram showing one example of the structure of a semiconductor integrated circuit device according to one embodiment of the present invention;

FIG. 2 is a circuit diagram showing one example of the structure of an expected-value generating circuit and a comparing and determining circuit in the semiconductor integrated circuit device shown in FIG. 1;

FIG. 3A is a chart showing one example of an output waveform from an I/F unit in the semiconductor integrated circuit device shown in FIG. 2;

FIG. 3B is a chart showing one example of an output waveform from the expected-value generating circuit in the semiconductor integrated circuit device shown in FIG. 2;

FIG. 3C is a chart showing one example of an output waveform from the comparing and determining circuit in the semiconductor integrated circuit device shown in FIG. 2;

FIG. 4 is a block diagram showing one example of the structure of the semiconductor integrated circuit device shown in FIG. 1 including a detailed example of an output processing circuit;

FIG. 5 is a block diagram showing one example of the structure of the semiconductor integrated circuit device shown in FIG. 1 including an example of the I/F unit and clock wiring;

FIG. 6A is a waveform diagram showing one example of signal waveforms of external signals in the semiconductor integrated circuit device shown in FIG. 5;

FIG. 6B is a waveform diagram showing one example of signal waveforms of internal signals in the semiconductor integrated circuit device shown in FIG. 5;

FIG. 7 is a circuitry diagram showing one example of the detailed structure of the semiconductor integrated circuit device shown in FIG. 5;

FIG. 8A is a schematic functional block diagram for describing one example of a clock adjusting function included in the semiconductor integrated circuit device according to one embodiment of the present invention;

FIG. 8B is a schematic operation waveform diagram for describing one example of a clock adjusting function included in the semiconductor integrated circuit device according to one embodiment of the present invention; and

FIG. 9 is a block diagram showing one example of a structure obtained by modifying the structure of the semiconductor integrated circuit device according to one embodiment of the present invention shown in FIG. 4.

### DESCRIPTION OF THE PRE EMBODIMENTS

An embodiment of the present invention is described in detail below based on the drawings. Here, throughout all drawings for describing the embodiment, the same members are, in principle, provided with the same reference numerals, and are not repeatedly described herein.

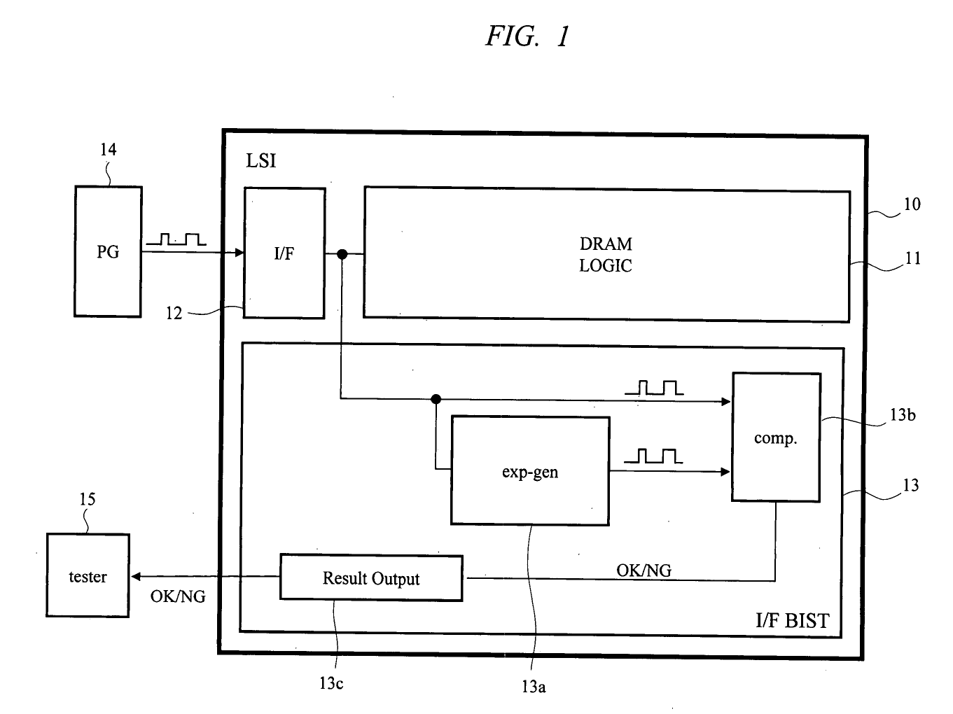

FIG. 1 is a block diagram showing one example of the structure of a semiconductor integrated circuit device according to one embodiment of the present invention. A semiconductor integrated circuit device (LSI) 10 includes, for example, a memory circuit 11 including a memory core, such as Dynamic RAM (DRAM), an I/F unit 12 of the memory circuit 11, and an I/F-BIST circuit 13 for testing the I/F unit 12.

The I/F-BIST circuit 13 includes an expected-value generating circuit (exp-gen) 13a that receives an input of an output signal from the I/F unit 12 to the memory circuit 11, a comparing and determining circuit (comp) 13b that receives an input of the output signal from the I/F unit 12 and an output signal from the expected-value generating circuit 13a, sequentially compares these two inputs, and determines whether these inputs match (OK) or does not match (NG) with each other, and an output processing circuit (Result Output) 13c that retains the determination result of the comparing and determining circuit 13b and performs a process for externally outputting the determination result. Here, it is assumed in FIG. 1 that an input is supplied by a pulse generator (PG) 14, and the determination result retained in the output processing circuit 13c is read by a tester 15.

In the above-structured semiconductor integrated circuit device, when a test pattern for testing the I/F unit 12 is input from the pulse generator 14 to the I/F unit 12, the output signal from the I/F unit 12 is input to the expected-value generating circuit 13a and the comparing and determining circuit 13b. Upon reception of the output signal from the I/F unit 12, the expected-value generating circuit 13a predicts a correct output signal, and then generates an expected-value signal for detecting an error in the output signal from the I/F unit 12. The comparing and determining circuit 13b sequentially compares the output signal from the I/F unit 12 and the expected-value signal for determination, and then outputs the determination result to the output processing circuit 13c. The output processing circuit 13c retains the determination result from the comparing and determining circuit 13b, and then outputs the determination result upon request from the tester 15.

The above-described structure and operation allow the I/F unit 12 to be tested. At this time, a test pattern is input by using the pulse generator 14, for example, and then comparison and determination are performed inside the LSI. Therefore, a test can be performed at a high-speed rate, such as several GHz. Also, the tester 15 has only to read the determination result retained by the output processing circuit 13c after the test is completed, for example, and therefore the tester 15 can operate at a low speed.

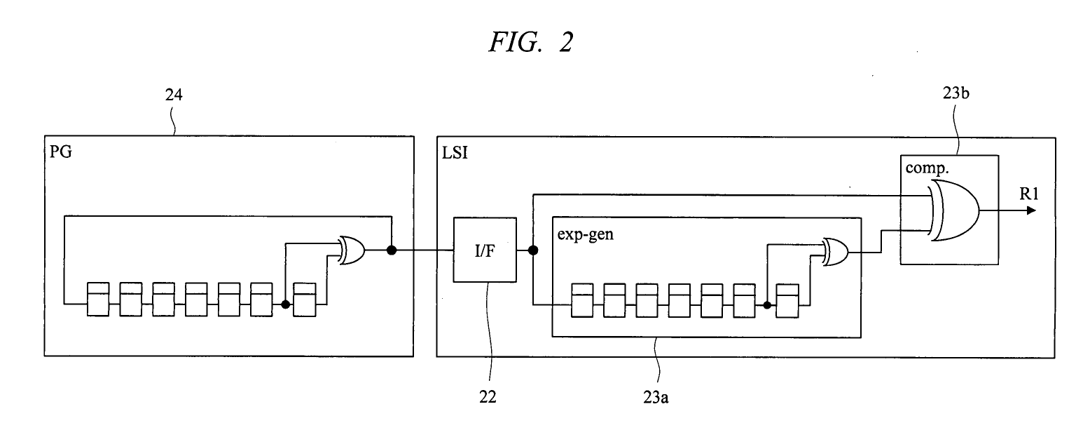

Next, one example of the structure of the expected-value generating circuit 13a and the comparing and determining circuit 13b shown in FIG. 1 is described. FIG. 2 is a circuit diagram showing one example of the structure of the expected-value generating circuit and the comparing and determining circuit in the semiconductor integrated circuit device shown in FIG. 1. FIG. 2 also shows one example of a pattern generation logic of the pulse generator 14.

An expected-value generating circuit 23a shown in FIG. 2 includes, for example, a shift register of seven stages supplied with the output signal from an I/F unit 22 and an EXOR circuit receiving inputs of an output signal from a sixth one of the stages and an output signal from a seventh one of the stages. An output signal from the EXOR circuit is input to the comparing and determining circuit 23b. The comparing and determining circuit 23b includes an EXOR circuit receiving inputs of an output signal from the expected value generating circuit 23a and an output signal from the I/F unit 22.

The expected-value generating circuit 23a supports a pattern generation logic of a pulse generator 24 shown in FIG. 2. That is, the pattern generation logic of the pulse generator 24 shown in FIG. 2 is a logic of generating an M-series pseudo-random-number pattern, such as PRBS (Pseudo Random Binary Sequence). By way of example, FIG. 2 shows, in a shift register including seven stages, an M-series pattern generation logic in which the output from the sixth stage and the output from the seventh stage are used as an input logic for the EXOR circuit and an output signal from the EXOR circuit is fed back to an input to the first stage in a loop. In correspondence with this pattern generation logic, the expected-value generating circuit 23a shown in FIG. 2 includes a shift register having the same number of stages and an EXOR circuit having the same input logic. However, an output signal from this EXOR circuit is not fed back in a loop.

As well known, there are various examples of the M-series pattern generation logic with different combinations of the number of stages and the input logic of the EXOR circuit. A majority of general pulse generator includes a function of generating such an M-series pseudo-random-number pattern, and the pattern generation logic can be arbitrary set to some extent. Here, different pattern generation logics of the pulse generator 24 require different shift registers and EXOR circuits to be provided in the expected-value generating circuit 23a corresponding to the number of stages and the input logic.

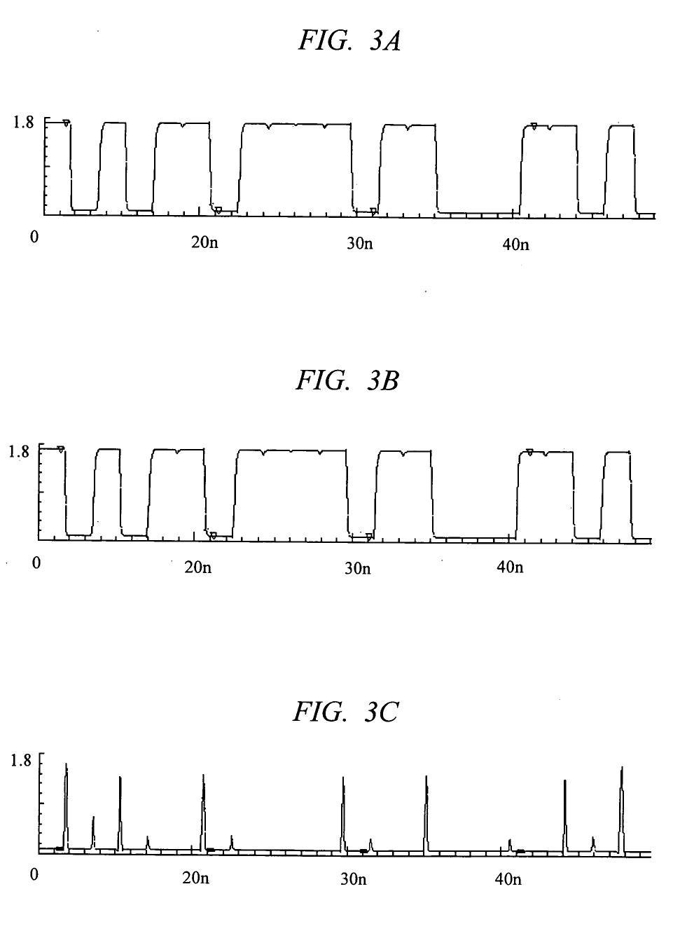

Next, the operation of the semiconductor integrated circuit device shown in FIG. 2 is described with reference to FIGS. 3A to 3C. FIG. 3A is a chart showing one example of an output waveform from an I/F unit in the semiconductor integrated circuit device shown in FIG. 2. FIG. 3B is a chart showing one example of an output waveform from the expected-value generating circuit in the semiconductor integrated circuit device shown in FIG. 2. FIG. 3C is a chart showing one example of an output waveform from the comparing and determining circuit in the semiconductor integrated circuit device shown in FIG. 2.

First, the pulse generator 24 outputs a pseudo-random-number pattern to the I/F unit 22. When signal transmission to the I/F unit 22 has no error, an output waveform of the I/F unit 22 is as shown in FIG. 3A, for example, in which an output waveform of the pulse generator is transmitted as it is by the I/F unit 22. Also, the expected-value generating circuit 23a includes the shift register having the same number of stages as that of the pulse generator 24 and the EXOR circuit having the same input logic as that of the pulse generator 24 to generate an expected value upon reception of the output signal from the pulse generator 24. Therefore, an output waveform of the expected-value generating circuit 23a is as shown in FIG. 3B That is, in inputs to the comparing and determining circuit 23b, the output signal from the I/F unit 22 and the output signal from the expected-value generating circuit 23a have the same phase and the same waveform. Therefore, an output signal R1 from the comparing and determining circuit 23 has a waveform as shown in FIG. 3C, and “L” data indicative of matching is output. Here, as shown in FIG. 3C, the output waveform includes fine hazards, which can be removed at latch timing of the output processing circuit, which will be described further below.

On the other hand, when signal transmission to the I/F unit 22 has an error, such as a bit error or cycle shift, an input signal to the pulse generator 24 fed back after being output from the pulse generator 24 is different from an input signal to the expected-value generating circuit 23a input via the I/F unit 22 after being output from the pulse generator 24. Therefore, due to the property of the M-series pattern, the output signal from the I/F unit 22 and the output signal from the expected-value generating circuit 23a always have at least one clock cycle in which these output signal do not match with each other. Therefore, although not shown, the output signal R1 from the comparing and determining circuit 23b includes “H” data for at least one cycle.

The above-described structure and operation allow the I/F unit to be tested by using an M-series pseudo-random-number pattern. Having high randomness, the M-series pseudo-random-number pattern can be suited for testing the I/F unit. Also, with the use of such a pattern, the expected-value generating circuit or the like can be easily configured.

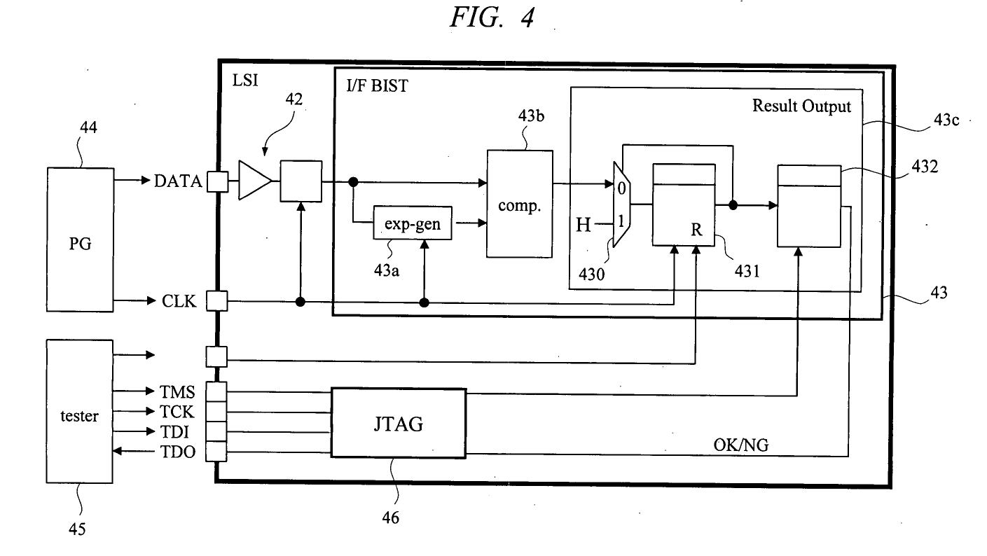

Next, one example of the structure of the output processing circuit 13c of shown FIG. 1 is described. FIG. 4 is a block diagram showing one example of the structure of the semiconductor integrated circuit device shown in FIG. 1 including a detailed example of an output processing circuit. Here, FIG. 4 also depicts an example of main external input and output signals and their connecting relation.

As with FIG. 1, the semiconductor integrated circuit device shown in FIG. 4 includes an I/F unit 42 and I/F-BIST circuit 43 including an expected-value generating circuit 43a, a comparing and determining circuit 43b, and an output processing circuit 43c. In addition, a Joint Test Action Group (JTAG) circuit 46 is also provided. The output processing circuit 43c includes, for example, a selector 430 that receives inputs of an output signal from the from the comparing and determining circuit 43b and an “H” fixed signal, a latch register 431 that receives an input of an output signal from the selector 430 and outputs a selection signal of the selector 430, and a read register 432 that receives an input of an output signal from the latch register 431 and outputs a signal, which is coupled to the JTAG circuit 46.

In the selector 430 and the latch register 431, once an “H” output signal from the comparing and determining circuit 43b is taken in, the input of the selector 430 is switched to continuously retain the “H” signal. Also, the retained “H” signal is cleared by a reset (R) input to an “L” signal. The read register 432 uses a control signal to take in the value retained in the latch register 431, and then transmits the value to the JTAG circuit 46.

Also, the same clock signal (CLK) is coupled to the I/F unit 42, the expected-value generating circuit 43a, and the latch register 431 in the output processing circuit 43c. Here, it is assumed in FIG. 4 that this clock signal is input from a pulse generator 44 and input data to the I/F unit 42 is also input from the pulse generator 44. It is also assumed that TMS, TCK, and TDI signals are input from a tester 45 to the JTAG circuit 46, and the JTAG circuit 46 outputs a TDO signal to the tester 45.

In the above-described structure, when the pulse generator 44 outputs a test pattern to the I/F unit 42, the I/F unit 42 is started to be tested by the expected-value generating circuit 23a and the comparing and determining circuit 23b as shown in FIG. 2, for example. At this time, the same clock signal is input to the I/F unit 42 and the expected-value generating circuit 43a. In an output from the comparing and determining circuit 43b, fine hazards occur as shown in FIG. 3C due to circuitry delay, wiring delay and the like. However, since the same clock signal is also input to the latch register 431, such hazards are not taken into the latch register 431.

On the other hand, when signal transmission to the I/F unit 42 has an error, an “H” signal for at least one clock cycle is output from the comparing and determining circuit 43b. The latch register 431 then takes in and latches this “H” signal. Then, after the test is completed, for example, the tester 45 uses TMS, TCK, and TDI signals to generate an instruction of reading the test result for the JTAG circuit 46. The JTAG circuit 46 provides a clock signal or the like to the read register 432 to read the test result, and then uses a TDO signal for transmitting the result to the tester 45.

Here, any circuit widely known under the standards can by used as the JTAG circuit 46. Also, when the JTAG circuit is used for reading the test result, for example, communication can be performed by not only the tester but also a personal computer, for example, thereby further reducing test cost. As a matter of course, the structure may be such that a control circuit that reads a value of the read register 432 and an external terminal are provided without using the JTAG circuit 46.

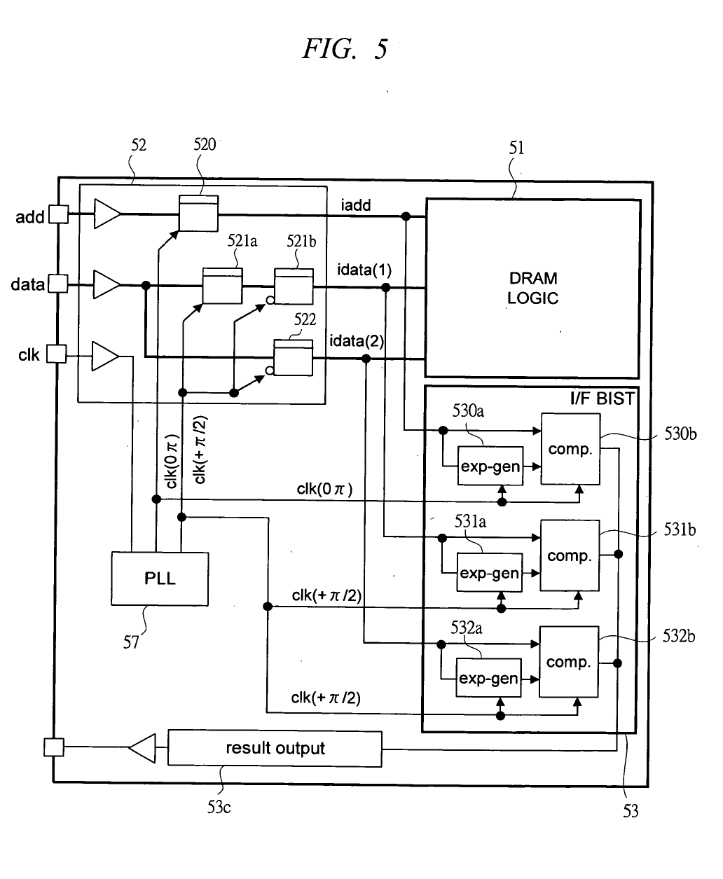

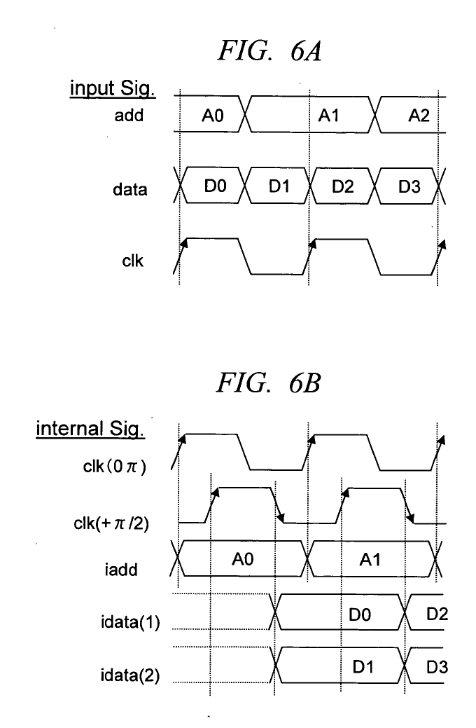

Next, one example of the structure of the semiconductor integrated circuit device with a general I/F unit provided in the memory circuit being targeted for testing is described. FIG. 5 is a block diagram showing one example of the structure of the semiconductor integrated circuit device shown in FIG. 1 including an example of the I/F unit and clock wiring. FIG. 6A is a waveform diagram showing one example of signal waveforms of external signals in the semiconductor integrated circuit device shown in FIG. 5, and FIG. 6B is a waveform diagram showing one example of signal waveforms of internal signals in the semiconductor integrated circuit device shown in FIG. 5.

In FIG. 5, an address signal (add), a data signal (data), and a clock signal (clk) are input from external terminals to an I/F unit 52. Also, an internal address signal (iadd) and internal data signals of two systems (idata(1) and idata(2)) are inputted via the I/F unit 52 to a memory circuit 51 and a I/F-BIST circuit 53. The clock signal is input to a Phase Locked Loop (PLL) circuit 57, in which an internal clock signal (clk(0π)) and an internal signal (clk(+π/2)) shifted therefrom by half cycle are generated.

The internal address signal (iadd) is output from a register 520 operating at a leading edge of the internal clock signal (clk(0π)). The internal data signals of two systems (idata(1) and idata(2)) support a double-data-rate scheme. The internal data signal of a first system (idata(1)) is output by, for example, two registers 521a and 521b connected together in series. The register 521a takes in a data signal at a leading edge of the internal clock signal (clk(+π/2)), while the register 521b latches and output an output from the register 521a at a trailing edge of the internal clock signal (clk(+π/2)). On the other hand, the internal data signal of a second system (idata(2)) is output, upon reception of the internal clock signal (clk(+π/2)), from a single register 522 that takes in a data signal at its trailing edge.

The I/F-BIST circuit 53 is provided with expected-value generating circuits 530a, 531a, and 532a of three systems and comparing and determining circuits 530b, 531b, and 532b of three systems, respectively corresponding to the internal address signal (iadd) and the two internal data signals (idata(1) and idata(2)). The expected-value generating circuit 530a and the comparing and determining circuit 530b, which correspond to the internal address signal (iadd), operate at a leading edge of the internal clock signal (clk(0π)), as in output timing of the internal address signal (iadd). The expected-value generating circuit 531a and the comparing and determining circuit 531b, which correspond to the internal data signal (idata(1)), and the expected-value generating circuit 532a and the comparing and determining circuit 532b, which correspond to the internal data signal (idata(2)), operate at a trailing edge of the internal clock signal (clk(+π/2)), as in output timing of the internal data signals (idata(l) and idata(2)).

Here, in FIG. 5, it is assumed for convenience of description that the comparing and determining circuits 530b, 531b, and 532b include the latch register 431 of the output processing circuit 43c described with reference to FIG. 4. Also, the clock signals for use in the expected-value generating circuits 530a, 531a, and 532a and the comparing and determining circuits 530b, 531b, and 532b for each signal system are not restricted to the above, but may be any signals as long as input timing to the comparing and determining circuit and latch timing of the latch register are based on the same clock signal.

In the above-described structure, when the clock signal (clk), and the address signal (add) and the data signal (data), which form a pseudo-random-number pattern, as shown in FIG. 6A are input by a pulse generator, for example, the internal clock signals (clk(0π) and clk(+π/2)), the internal address signal (iadd), and the internal data signals (idata(1) and idata(2)) as shown in FIG. 6B are generated. Then, tests are performed by using the expected-value generating circuits 530a, 531a, and 532a and the comparing and determining circuits 530b, 531b, and 532b corresponding to the internal address signal (iadd) and the internal data signals (idata(1) and idata(2)), respectively. The respective comparison and determination results are output from an output processing circuit 53c to the outside.

As such, by providing the expected-value generating circuit and the comparing and determining circuit for each different signal system, an I/F unit of a double-data-rate scheme or the like can be supported. Also, a test can be performed with an appropriate test pattern for each signal system, and tests for the signal systems can be simultaneously performed. Furthermore, comparison and determination can be performed for each signal system, thereby easily locating a malfunction.

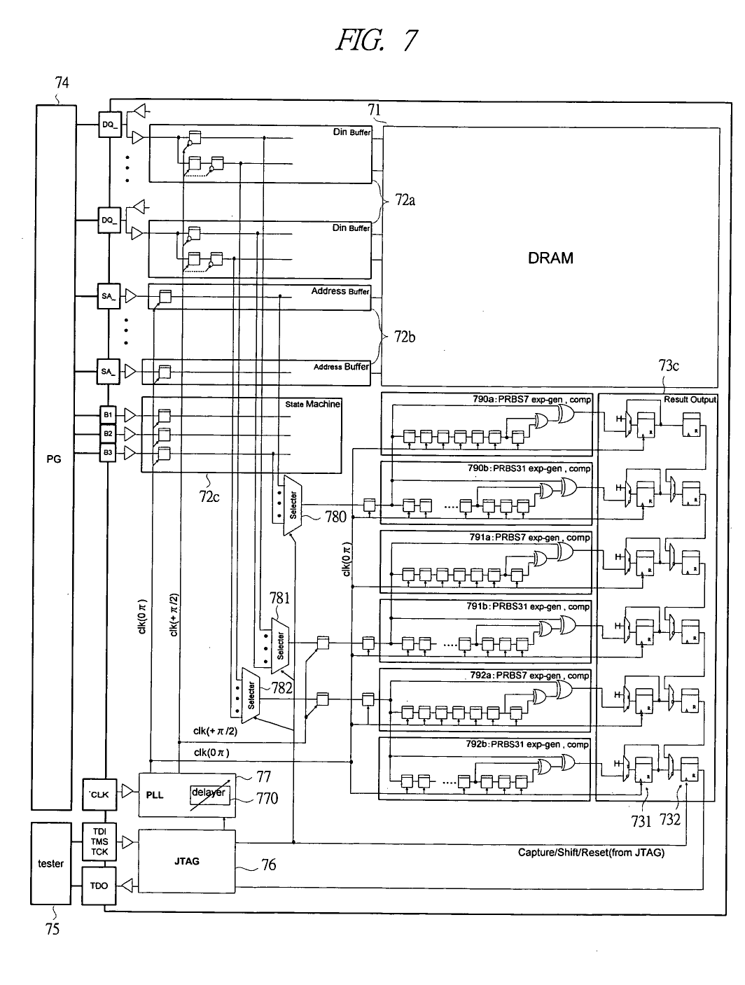

Next, a more specific example of the structure shown in FIG. 5 is described by using FIG. 7. FIG. 7 is a circuitry diagram showing one example of the detailed structure of the semiconductor integrated circuit device shown in FIG. 5. The semiconductor integrated circuit device shown in FIG. 7 includes, for example, a clock terminal (CLK) and a plurality of address terminals (SA) and control input terminals (B1, B2, and B3) as external input terminals for a memory circuit (DRAM) 71, and a plurality of data terminals (DQ) as an external input/output terminal. Furthermore, as external terminals for a JTAG circuit 76, as with FIG. 4, TDI, TMS, TCK, and TDO terminals are provided.

The clock terminal (CLK) is connected to a PLL circuit 77, where internal clock signals (clk(0π) and clk(+π/2)) are generated. The plural address terminals (SA) are connected to address buffers 72b serving as I/F units. These plural address buffers 72b are each supplied with the internal clock signal (clk(0)). The plural control input terminals (B1, B2, and B3) are connected to a state machine 72c serving as an I/F unit. The state machine 72c is supplied with the internal clock signal (clk(+π/2)). The plural data terminals (DQ) are connected to data input buffers (Din Buffer) serving as I/F units. These plural data input buffers 72a are supplied with the internal clock signal (clk(+π/2).

Here, the plural address buffer 72b and the state machine 72c operate with the same clock signal and have the same structure, and therefore of the same signal system. Also, the plural data input buffers 72a can be classified into two signal systems, as in FIG. 5. Therefore, in FIG. 7, selectors 780, 781, and 782 are provided for output signals from the plural address buffer 72b and the state machine 72c, an output signal from data input buffers 72a of a first system, and an output signal from data input buffers 72a of a second system, respectively. With each of these selectors 780, 781, and 782, an arbitrary one of the plural signals of the same system can be selected.

An output signal from the selector 780 corresponding to the address, for example, is input to determining circuits 790a and 790b of two types having different circuit configurations, and the determination results are output to a latch register 731 of an output processing circuit 73c. Here, the determining circuits include such an expected-value generating circuit and a comparing and determining circuit as those described above. The determining circuit 790a of a first type includes, for example, an M-series expected-value generating circuit (PRBS7) including a shift register having seven stages, while the determining circuit 790b of a second type includes, for example, an M-series expected-value generating circuit (PRBS31) including a shift register having thirty-one stages.

Similarly, an output signal from the selector 781 corresponding to data of the first system is coupled via determining circuits 791a and 791b of two types having different circuit configurations to the latch register 731 of the output processing circuit 73c. And an output signal from the selector 782 corresponding to data of the second system is coupled via determining circuits 792a and 792b of two types having different circuit configurations to the latch register 731 of the output processing circuit 73c. To an output from each latch register 731, a read register 732 is coupled. The value of the read register 732 can be read through a scan chain from the JTAG circuit 76.

Here, in FIG. 7, a register operating with the internal clock signal (clk(0π)) is provided between the selector 780 and the determining circuits 790a and 790b. Also, a register operating with the internal clock signal (clk(+π/2)) and, subsequently thereto, a register operating with the internal clock signal (clk(0π)) are provided between the selectors 781 and 782 corresponding to the data and the determining circuits 791a, 791b, 792a and 792b. That is, all of the determining circuits 790a to 792a, 790b to 792b, and the latch registers 731 of the output processing circuit 73 can operate only with the internal clock signal (clk(0π)).

In the above-described structure, when a test pattern is input from a pulse generator 74, for example, one signal selected for each of the selectors 780 to 782 is input to the relevant determining circuits of two systems for testing. At this time, when the input test pattern from the pulse generator 74 is an M-series pattern for a seven-stage shift register and the I/F unit is normal, the determining circuits 790a to 792a each including an expected-value generating circuit having seven stages output an “L”, while the determining circuits 790b to 792b each including an expected-value generating circuit having thirty-one stages output an “H”. As a matter of course, when the input test pattern is an M-series pattern for a thirty-one-stage shift register, reversed results are obtained.

Therefore, when the I/F unit is normal, the test results read in serial from the read registers 732 of the output processing circuit 73c are “101010” or “010101”. Then, upon completion of the test for one signal selected for each of the selectors 780 to 782, a selection signal from the each of the selectors 780 to 782 is supplied by the JTAG circuit 76, for example, thereby allowing the next one signal to be selected for testing in a similar manner as described above.

As such, by providing expected-value generating circuits of a plurality of types, a test with higher coverage can be performed. This is also useful in checking the I/F-BIST circuit itself. Furthermore, determining circuits of the same system is handled by a single selector, thereby significantly reducing the circuit size. In principle, a determining circuit or the like can be provided for each and every terminal. In practice, however, handling for each system is more practical in view of the above-described circuit-size problem and the number of simultaneously-measured channels.

Also, in recent years, a problem likely occurs such that a cause for malfunction is present between an external input and a terminal (pad) of the semiconductor integrated circuit device due to wiring inside the package or a transmission path on the substrate, thereby causing a malfunction seemingly as a malfunction in the I/F unit. Normally, it takes time to track down the cause for such a case. However, with the structure as shown in FIG. 7, all terminals can be tested to easily locate a malfunctioned terminal, thereby allowing the problem as described above to be solved early.

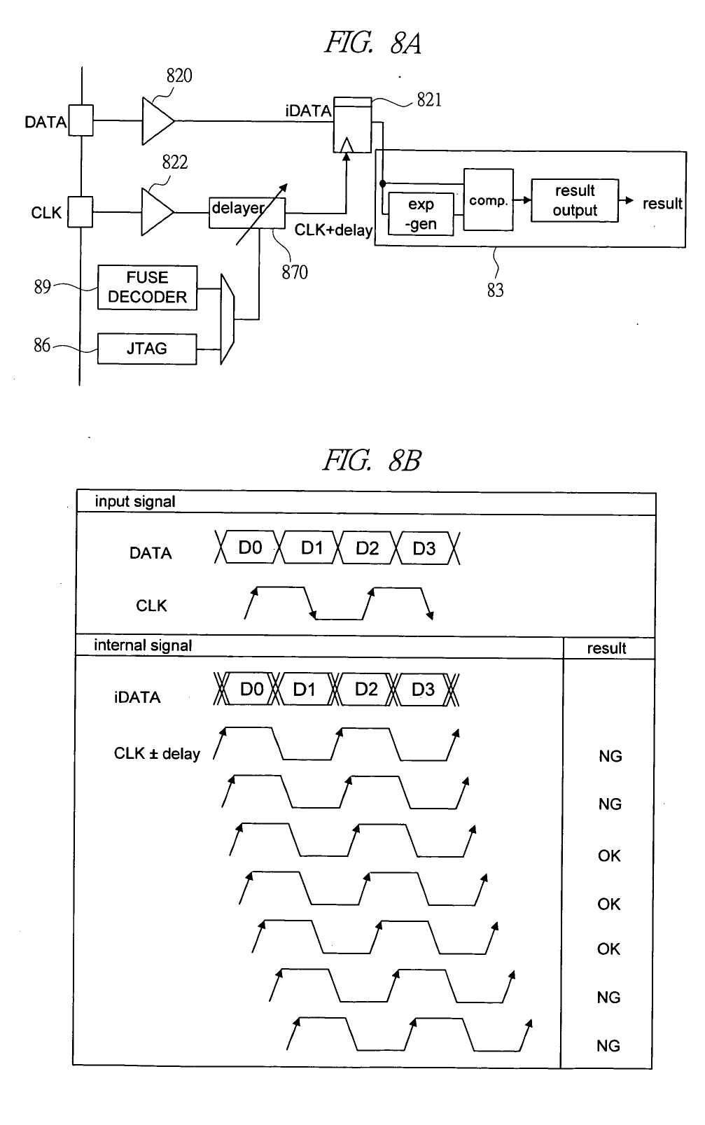

The PLL circuit 77 shown in FIG. 7 can include, for example, a variable delayer circuit (Delayer) 770 as shown in FIG. 7. However, this variable delayer circuit 770 needs provided only for the clock signal, and therefore is not required to be inside the PLL circuit 77. With the use of this variable delayer circuit 770 and the above-described I/F-BIST circuit, an operation margin of the LSI can be enhanced, as shown in FIG. 8, for example. FIG. 8A is a schematic functional block diagram for describing one example of a clock adjusting function included in the semiconductor integrated circuit device according to one embodiment of the present invention. And FIG. 8B is a schematic operation waveform diagram for describing one example of the clock adjusting function.

In FIG. 8A, a clock signal (CLK) and a data signal (DATA) are externally provided. The externally-provided data signal is input to an I/F unit including an input driver 820 and a register 821. An output signal from the register 821 is then inputted to an I/F-BIST circuit 83 including an expected-value generating circuit (exp-gen), a comparing and determining circuit (comp), and an output processing circuit (result output). On the other hand, the clock signal is supplied via an input driver 822 and a variable delayer circuit (Delayer) 870 to the register 821 for the data signal. A delay time of the variable delayer circuit 870 can be set by a JTAG circuit 86 or a fuse circuit (FUSE DECODER) 89.

In the above-described structure, a test is first performed by the I/F-BIST circuit 83 while the JTAG circuit 86 is being used to change the delay time of the clock signal in sequence, as shown in FIG. 8B. From the test results (result), a position of the clock signal where a largest margin can be obtained is found. In the test results shown in FIG. 8B, the position is a center position of three consecutive OKs. Then, the set value of the delay time is held on a non-volatile element, such as the fuse circuit 89. In actual operation of the LSI, the delay time fixed by the fuse circuit 89 is used, thereby increasing the operation margin of the LSI.

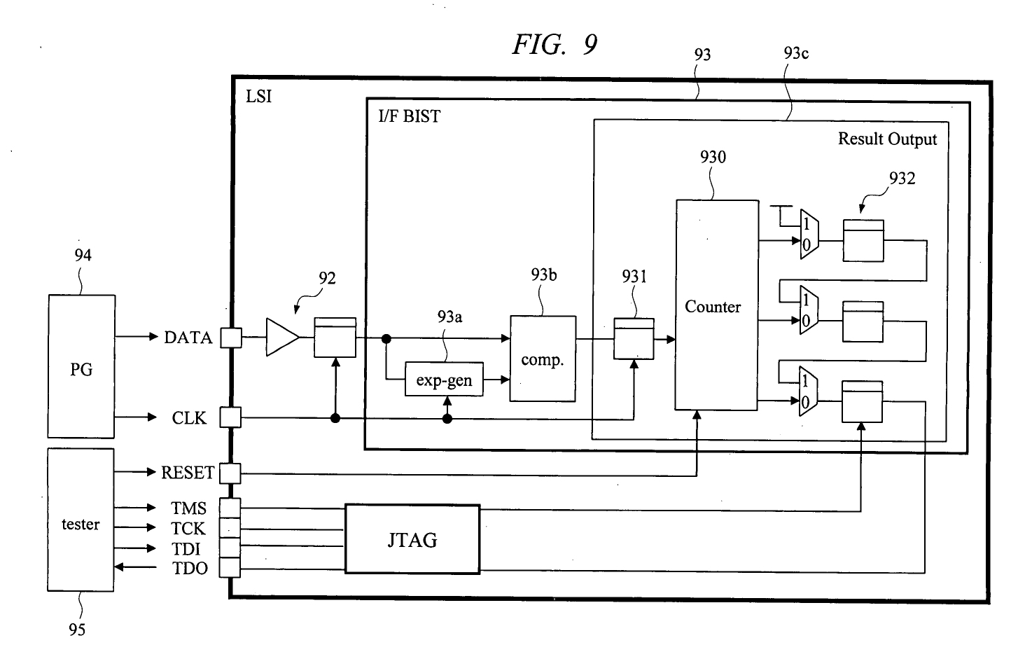

Next, one example of the structure obtained by modifying the structure shown in FIG. 4 is described. FIG. 9 is a block diagram showing one example of a structure obtained by modifying the structure of the semiconductor integrated circuit device according to one embodiment of the present invention shown in FIG. 4. The semiconductor integrated circuit device shown in FIG. 4 is different in structure from that shown in FIG. 1 in that a counter circuit 930 is provided in an output processing circuit 93c.

The output processing circuit 93c includes a register 931 that takes in an output from a comparing and determining circuit 93b, the counter circuit 930 that performing counting when an output from the register 931 is an “H” signal, and a read register 932 provided correspondingly to the number of output bits from the counter circuit for reading the value of the counter circuit 930 under the control of a JTAG circuit 96. Here, the read register 932 has a scan-chain structure, and can output values in serial under the control of the JTAG circuit 96.

With the above-described structure, a bit error rate or the like can be found in detail, for example. Also, in combination of the above-described clock adjusting function, a malfunction analyzing function can be usefully achieved.

The invention devised by the inventors has been specifically described based on the embodiment. Needless to say, however, the present invention is not restricted to the embodiment described above, and can be variously modified without departing from the gist of the present invention.

Typical effects achieved by the present invention disclosed in the specification are briefly described below.

With provision of a circuit that generates an expected-value signal upon reception of an output signal directed from the interface unit to the internal processing circuit and a circuit that compares the output signal from the interface unit and the expected-value signal to determine whether these signals match with each other, the interface unit can be tested without using a memory tester. Therefore, memory LSI testing can be facilitated.

The semiconductor integrated circuit device according to the present invention is useful by being applied to a memory LSI, memory-combined LSI or the like, equipped with a high-speed memory and its interface. However, this is not meant to be restrictive. Furthermore, the semiconductor integrated circuit device can be widely applied to general LSIs that require high-speed signal transmission.

1. A semiconductor integrated circuit device comprising:
an interface circuit that takes in an externally input signal and outputs the taken-in input signal to an internal processing circuit;
a circuit that generates, upon receiving the output signal from the interface circuit, an expected-value signal for detecting an error in signal transmission in the interface circuit;
a comparing and determining circuit that compares the output signal from the interface circuit and the expected-value signal to determine whether the output signal and the expected-value signal match with each other; and
an output processing circuit that retains the determination result of the comparing and determining circuit and performs a process for externally outputting the determination result upon external request.

2. The semiconductor integrated circuit device according to claim 1, wherein
the externally input signal is a pseudo-random-number signal generated by a first shift register having a specific number of stages and an input logic of a first EXOR circuit to the shift register, and
the circuit that generates the expected-value signal includes:
a second shift register having a number of stages equal to the specific number of stages of the first shift register; and
a second EXOR circuit having an input logic identical to the input logic of the first EXOR circuit.

3. The semiconductor integrated circuit device according to claim 1, wherein
the internal processing unit is a memory circuit.

4. A semiconductor integrated circuit device comprising:
an interface circuit that takes in a preset input test pattern in synchronization with a clock signal and outputs the preset input test pattern to an internal processing circuit;
a circuit that predicts, based on the preset input test pattern, an output pattern directed from the interface circuit to the internal processing circuit and generates an expected value pattern for detecting whether an error is present in the output pattern; and
a comparing and determining circuit that compares, for each cycle of the clock signal, the output pattern and the expected value pattern and generates either one of a matching signal and a non-matching signal.

5. The semiconductor integrated circuit device according to claim 4, further comprising a circuit that delays the clock signal in accordance with an externally set value.

6. The semiconductor integrated circuit device according to claim 4, further comprising a counter circuit that counts the number of occurrence of the non-matching signals.

7. The semiconductor integrated circuit device according to claim 5, further comprising a circuit that holds a delay set value of the clock signal in a non-volatile state.

8. A semiconductor integrated circuit device comprising:
a first interface circuit that receives an input of an address test pattern, takes in the input address test pattern in synchronization with a clock signal, and outputs a first output pattern to an internal memory circuit;
a second interface circuit that receives an input of a data test pattern, takes in the input data test pattern in synchronization with the clock signal, and outputs a second output pattern to an internal memory circuit;
a first expected-value generating circuit that generates a first expected-value pattern upon reception of the first output pattern;
a second expected-value generating circuit that generates a second expected-value pattern upon reception of the second output pattern;
a first comparing and determining circuit that compares the first output pattern and the first expected-value pattern and determines whether or not the first output pattern and the first expected-value pattern match with each other;
a second comparing and determining circuit that compares the second output pattern and the second expected-value pattern and determines whether or not the second output pattern and the second expected-value pattern match with each other; and
an output processing circuit that retains the determination result of the first comparing and determining circuit and the determination result of the second comparing and determining circuit respectively, and performs a process for externally outputting the decision result upon external request, wherein
the address test pattern and the data test pattern are each generated by a first shift register having a specific number of stages and an input logic of a first EXOR circuit to the shift register,
the first expected-value generating circuit includes a second shift register having a number of stages equal to the number of stages of the first shift register that generates the address test pattern and includes a second EXOR circuit having an input logic identical to the input logic of the first EXOR circuit, and
the second expected-value generating circuit includes a third shift register having a number of stages equal to the number of stages of the first register that generates the data test pattern and includes a third EXOR circuit having an input logic identical to the input logic of the first EXOR circuit.

9. The semiconductor integrated circuit device according to claim 8, wherein
either one of the first interface circuit and the second interface circuit is provided with a plurality of either of the first expected-value generating circuits and the second expected-value generating circuits having different structures and a plurality of either of the first comparing and determining circuits and the second comparing and determining circuits having different structures.

10. The semiconductor integrated circuit device according to claim 8, wherein
a plurality of the first interface circuits and a plurality of the second interface circuits are present, and
the semiconductor integrated circuit device further comprises:
a first selector circuit that receives inputs from the plurality of first interface circuits for output to one of the first comparing and determining circuits; and
a second selector circuit that receives inputs from the plurality of second interface circuits for output to one of the second comparing and determining circuits.

11. The semiconductor integrated circuit device according to claim 8, wherein
the second interface circuit includes:
a third interface circuit that takes in one piece of data of a double-data-rate scheme,
a fourth interface circuit that takes in another piece of the data of the double-data-rate scheme, and
the third interface circuit and the fourth interface circuit are each separately provided with the second expected-value generating circuit and the second comparing and determining circuit.
